(19) United States
(12) Patent Application Publication
(10) Pub. No.: US 2024/0209154 A1
(43) Pub. Date: Jun. 27, 2024

(54) POLYMER, DIELECTRIC FLUID, AND COOLING SYSTEM

(71) Applicant: INDUSTRIAL TECHNOLOGY RESEARCH INSTITUTE, Hsinchu (TW)

(72) Inventors: Chen-Kuang CHIANG, Taichung City (TW); Jyh-Long JENG, New Taipei City (TW); Hsiang-Yen TSAO, Zhubei City (TW)

(73) Assignee: INDUSTRIAL TECHNOLOGY RESEARCH INSTITUTE, Hsinchu (TW)

(21) Appl. No.: 18/184,034

(22) Filed: Mar. 15, 2023

(30) Foreign Application Priority Data
Dec. 7, 2022 (TW) 111146912

(51) Int. Cl. C08G 77/04; C08K 5/00; C09K 5/10

(52) U.S. Cl. CPC C08G 77/045; C08K 5/005; C09K 5/10

(57) ABSTRACT

A polymer is formed by reacting a terminating agent with a star polymer. The star polymer is formed by reacting a core molecule with a hydroxy terminated silicone oil. The core molecule includes a plurality of alkoxysilyl groups, a plurality of hydroxysilyl groups, or a combination thereof. The polymer can be mixed with antioxidant and metal deactivator to form a dielectric fluid, which can be used in a cooling system.

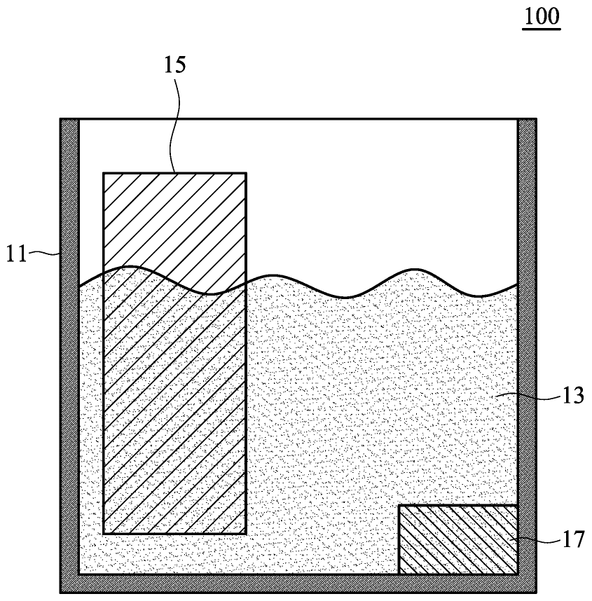

### CROSS REFERENCE TO RELATED APPLICATIONS

The present application is based on, and claims priority from, Taiwan Application Serial Number 111146912, filed on Dec. 7, 2022, the disclosure of which is hereby incorporated by reference herein in its entirety.

### TECHNICAL FIELD

The technical field relates to a polymer, and in particular it relates to a dielectric fluid containing the polymer and a cooling system utilizing the dielectric fluid.

### BACKGROUND

As the demand for high speed computing in electronic devices increases, and as the component packing density of said electronic devices rises, heat generation issues become critical, and have adverse effects on the performance of the electronic device, i.e. impacting computing efficiency, energy conversion, and durability. The current technology attempts to fill the electronic devices with a dielectric fluid to quickly dissipate the heat. The dielectric fluid has a mass viscosity, heat capacity, and thermal conductivity coefficient which are all higher than those of air, which can elevate the heat dissipation effect and lower the power consumption of the electronic device. However, commercially available dielectric fluids have shortcomings; due to its flammability, poor durability, and tendency to produce greenhouse gases and toxic decomposition residue.

Silicone oil is inherently degradable and bio-compatible. However,

conventional silicone oils have too low a flash point (<250° C.) and insufficient thermal stability. Accordingly, novel silicone oil is called for in order to serve as a dielectric fluid in a cooling system.

### SUMMARY

One embodiment of the disclosure provides a polymer, being formed by reacting a terminating agent with a star polymer, the star polymer is formed by reacting a core molecule with a hydroxy terminated silicone oil, and the core molecule includes a plurality of alkoxysilyl groups, a plurality of hydroxysilyl groups, or a combination thereof.

One embodiment provides a dielectric fluid, including 100 parts by weight of the polymer; 0.01 to 5 parts by weight of antioxidant; and 0.0001 to 0.01 parts by weight of metal deactivator.

One embodiment of the disclosure provides a cooling system, including a container the dielectric fluid disposed in the container; an electronic element partially or entirely immersed in the dielectric fluid, wherein heat generated by the electronic element is transferred to the dielectric fluid; and a heat exchanger disposed in the dielectric fluid for cooling the dielectric fluid.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

Figure shows a cooling system in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

One embodiment of the disclosure provides a polymer formed by reacting a terminating agent with a star polymer, and the star polymer is formed by reacting a core molecule with a hydroxy terminated silicone oil. The core molecule includes a plurality of alkoxysilyl groups, a plurality of hydroxysilyl groups, or a combination thereof. For example, the core molecule may have a chemical structure of

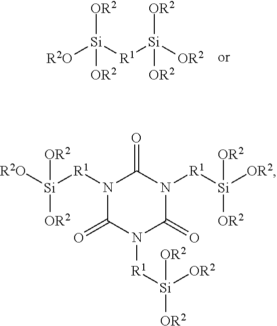

wherein each of R¹ is independently C₂₋₅ alkylene group, and each of R² is independently of H or C₁₋₃ alkyl group. In some embodiments, the core molecule includes 1,2-bis(triethoxysilyl)ethane, tris[3-(trimethoxysilyl)propyl] isocyanurate, or another suitable core molecule.

In some embodiments, the hydroxy terminated silicone oil has a chemical structure of

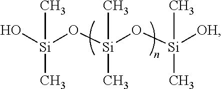

wherein n is a repeating number, and the hydroxy terminated silicone oil has a viscosity of 60 cP to 120 cP at 25° C. The n value is positively correlated to the viscosity and the molecular weight of the hydroxy terminated silicone oil. If the viscosity of the hydroxy terminated silicone oil at 25° C. is too high, the polymer will be unsuitable to serve as a dielectric fluid of a cooling system. If the viscosity of the hydroxy terminated silicone oil at 25° C. is too low, the reactivity of the star polymer will be too high and the star polymer will be easily crosslinked and gelled during the terminating step.

In some embodiments, the alkoxysilyl groups, hydroxysilyl groups, or a combination thereof in the core molecule and the hydroxy groups in the hydroxy terminated silicone oil have a molar ratio of 1:1.5 to 1:2.5. If the amount of the hydroxy groups of the hydroxy terminated silicone oil is too low, the polymer will have a flash point and a decomposition temperature (Td, 5% weight loss temperature) that are both too low. If there are too many hydroxy groups in the hydroxy terminated silicone oil, the excess hydroxy terminated silicone oil need to be further removed which increases the manufacturing cost.

In some embodiments, the terminating agent has a chemical structure of

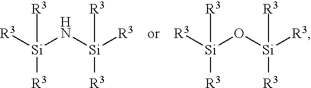

wherein each of R³ is independently of H, methyl group, or ethyl group. If R³ is a functional group with a high steric hindrance such as phenyl group or cyclohexyl group, the viscosity of the polymer will be increased.

In some embodiments, the alkoxysilyl groups, hydroxysilyl groups, or a combination thereof in the core molecule and the terminating agent have a molar ratio of 1:1 to 1:1.2. If the amount of the terminating agent is too low, the polymer that is not completely terminated may further crosslink to increase its viscosity. If the amount of the terminating agent is too high, the excess terminating agent needs to be further removed to which increases the manufacturing cost.

In some embodiments, the polymer has a chemical structure of

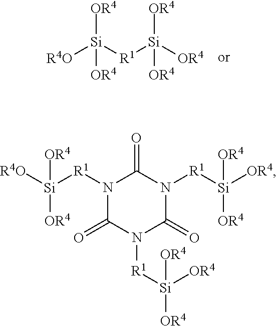

wherein each of R¹ is independently C₂₋₅ alkylene group, each of R⁴ is independently of

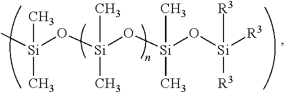

wherein n is a repeating unit, and each of R³ is independently of H, methyl group, or ethyl group.

For example, if the core molecule is

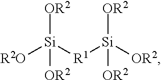

the core molecule will react with the hydroxy terminated silicone oil to form the star polymer as shown below.

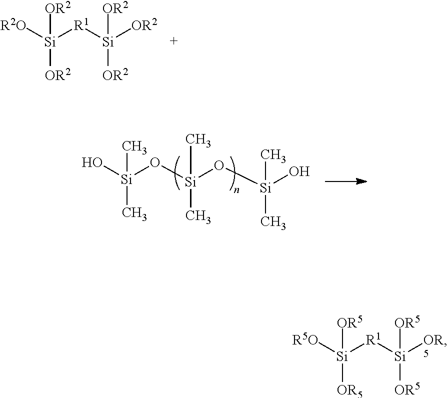

wherein R⁵ is

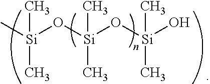

Subsequently, the terminating agent and the star polymer are mixed and reacted to form the polymer as shown below.

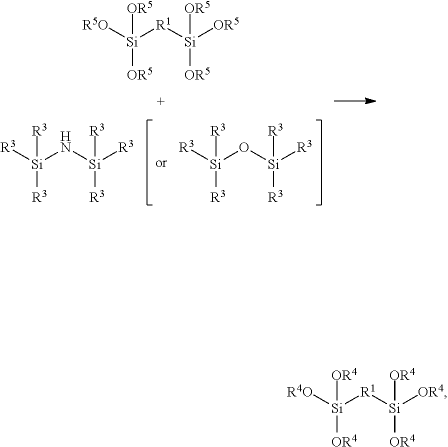

wherein R⁴ is

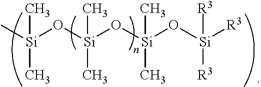

For example, if the core molecule is

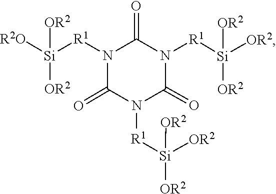

the core molecule and will react with the hydroxy terminated silicone oil to form the star polymer as shown in below.

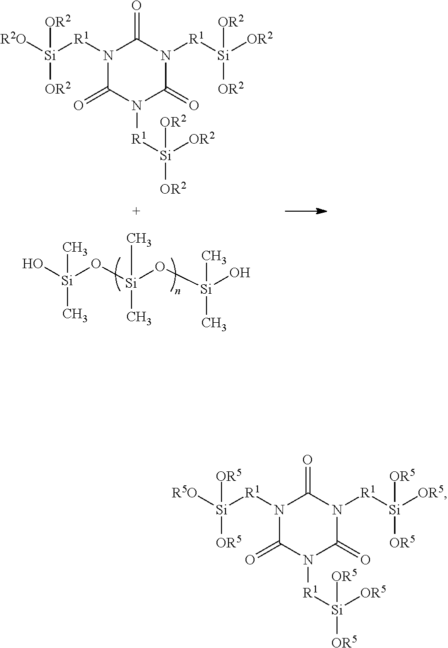

wherein R⁵ is

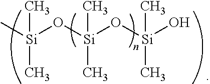

Subsequently, the terminating agent and the star polymer are mixed and reacted to form the polymer as shown below.

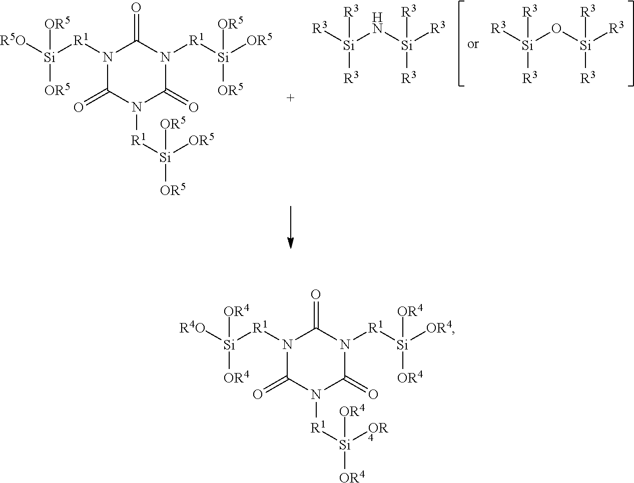

wherein R4 is

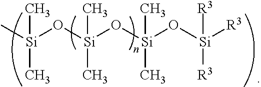

In some embodiments, the core molecule is reacted with the hydroxy terminated silicone oil in the presence of a catalyst, and the catalyst comprises formic acid, acetic acid, hydrochloric acid, or a combination thereof. For example, the total weight of the core molecule and the hydroxy terminated silicone oil and the volume of the catalyst have a ratio of 100:0.01 to 100:2. If the catalyst amount is too low, the catalyst effect will be insufficient and the reaction will need a longer reaction time or even cannot be performed. If the catalyst amount is too high, the reaction will be possibly crosslinked and gelled.

One embodiment provides a dielectric fluid including 100 parts by weight of the polymer; 0.01 to 5 parts by weight of antioxidant; and 0.0001 to 0.01 parts by weight of metal deactivator. If the antioxidant amount is too low, the viscosity of the dielectric fluid after being used for long period of time will be increased. If the antioxidant amount is too high, the dielectric fluid will be cured and crosslinked or have a much higher viscosity. If the metal deactivator amount is too low, the viscosity of the dielectric fluid after being used for long time period will be increased. If the metal deactivator amount is too high, precipitate will be solid precipitate will precipitate out from the dielectric fluid or the dielectric fluid will have a much higher viscosity.

In some embodiments, the antioxidant includes di-tert-butyl-p-cresol, 2,6-di-tert-butyl-4-methylphenol, 2,5-di-tert-butyl-hydroquinone, 2,6-di-tert-butyl-4-ethylphenol, 4,4-methylenebis-2,6-di-tert-butylphenol, N,N-di-second-butyl-p-phenylenediamine, alkylated diphenylamine, di-isooctyl di-aniline, octadecyl 3-(3,5-di-tert-butyl-4-hydroxyphenyl) propionate, or a combination thereof.

In some embodiments, the metal deactivator includes triazole compound or diazole compound. For example, the triazole compound can be 3-salicylamido-1,2,4-triazole, methylbenzotriazole, or a combination thereof.

In some embodiments, the dielectric fluid and the hydroxy terminated silicone oil have a difference in viscosity between 0.1 cP to 10 cP at 25° C. If the viscosity difference of the dielectric fluid and the hydroxy terminated silicone oil is too large, it means that the crosslink degree of the polymer in the dielectric fluid is too high. In general, the viscosity of the dielectric fluid is mainly influenced by the viscosity of the polymer. The viscosity of the commercially available silicone oil is positively correlated to the flash point and the decomposition temperature (Td, 5% weight loss temperature) of the commercially available silicone oil. In other words, the commercially available silicone oil having a low viscosity usually has a lower flash point and a lower decomposition temperature (Td, 5% weight loss temperature), and the commercially available silicone oil having a high viscosity usually has a higher flash point and a higher decomposition temperature (Td, 5% weight loss temperature). Accordingly, the commercially available silicone oil cannot simultaneously satisfy the requirements of low viscosity, high flash point, and high decomposition temperature (Td, 5% weight loss temperature). However, the polymer (formed by grafting a hydroxy terminated silicone oil to a core molecule, and then terminating the terminal hydroxy groups by the terminating agent) may achieve low viscosity, high flash point, and high decomposition temperature (Td, 5% weight loss temperature) at the same time.

Figure shows a cooling system 100 in one embodiment of the disclosure. The cooling system 100 includes a container 11. The dielectric fluid is disposed in the container 11, and an electronic element 15 can be partially or entirely immersed in the dielectric fluid 13. The electronic element 15 can be a transformer, a capacitor, a switch, a transmission component, a circuit, a resistor, another electronic element, or a combination thereof. Heat generated by the electronic element 15 can be transferred to the dielectric fluid 13 to lower the temperature of the electronic element 15. The cooling system 100 also includes a heat exchanger 17 disposed in the dielectric fluid 13 for cooling the dielectric fluid 13. The heat exchanger 17 can be any heat exchanger that is general in the skilled in the art, which can be collocated with any design such as a manifold or a stirring blade for improving the cooling effect. It should be understood that the cooling system 100 is only for illustration, and one skilled in the art may replace a dielectric fluid in a known cooling system utilizing the dielectric fluid with the dielectric fluid that is disclosed in the disclosure to improve the cooling effect.

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

In following examples, the viscosities of the polymers and the dielectric fluids at 25° C. were measured by the apparatus Brookfield viscometer. The aging tests of the polymers and the dielectric fluids were performed by the standard ASTM D1934 (115° C./96 hours). The decomposition temperatures (Td, 5% weight loss temperature) of the polymers and the dielectric fluids under atmosphere were measured by a heating rate of 20° C/minutes. The flash points of the polymers and the dielectric fluids were measured by the standard ASTM D92.

### Example 1

12.7 g of tris[3-(trimethoxysilyl)propyl] isocyanurate (1 part by mole) serving as a core molecule, 779.57 g of hydroxy terminated silicone oil (9 parts by mole, having a viscosity of 90 cP to 120 cP at 25° C., hydroxy terminated polydimethylsiloxane commercially available from Gelest, Inc.), and formic acid serving as catalyst were mixed and heated to 110° C., and then stirred for 24 hours to perform a sol-gel reaction, thereby obtaining a star polymer. The volume of the formic acid and the total weight of the core molecule and the hydroxy terminated silicone oil had a ratio of 0.5% (v/w). Subsequently, the formic acid catalyst and the side product methanol were removed by a rotary evaporator (10 torr,)140° C. The reaction is shown below:

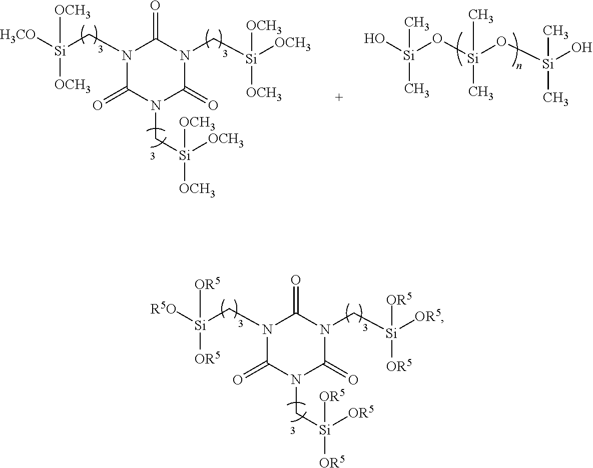

wherein R⁵ is

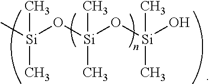

Subsequently, 9.95 g of hexamethyldisilazane (9 parts by mole) serving as a terminating agent was mixed with the star polymer, and then heated to 60° C. to react for 6 hours, thereby obtaining a polymer. The precipitate was filtered out, and the side product ammonia and the excess hexamethyldisilazane in the filtrate were removed by the rotary evaporator (10 torr,)140° C. The reaction is shown below

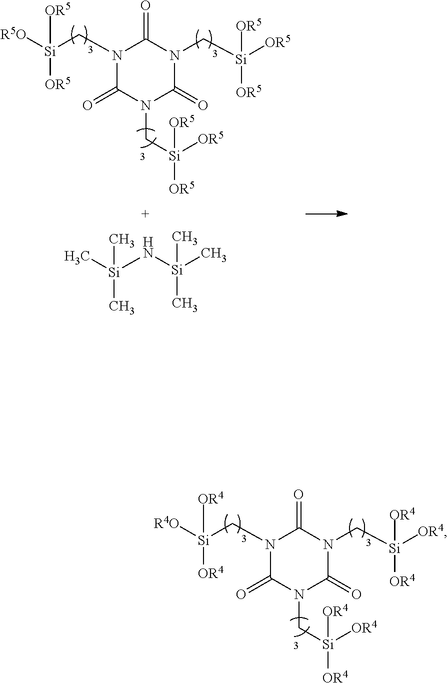

wherein R⁴ is

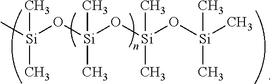

The polymer had a viscosity of 78 cP at 25° C., a viscosity at 25° C. after aging of 136 cP, a decomposition temperature

(Td, 5% weight loss temperature) of 248° C., and a flash point of 252° C.

### Example 2

2,6-Di-tert-butyl-p-cresol serving as antioxidant, 3-salicylamido-1,2,4-triazole serving as metal deactivator, and the polymer of Example 1 were mixed to form a dielectric fluid. The polymer and 2,6-di-tert-butyl-p-cresol had a weight ratio of 100:0.05, and the polymer and 3-salicylamido-1,2,4-triazole had a weight ratio of 100:0.001. The dielectric fluid had a viscosity of 80 cP at 25° C., a viscosity at 25° C. after aging of 85 cP, a decomposition temperature (Td, 5% weight loss temperature) of 249° C., and a flash point of 252° C. Accordingly, adding appropriate amounts of the antioxidant and the metal deactivator could keep rather than dramatically increase the viscosity of the dielectric fluid after being used at high temperature for a long period, which was beneficial to improve the durability of the dielectric fluid.

### Example 3

12.7 g of tris[3-(trimethoxysilyl)propyl] isocyanurate (1 part by mole) serving as a core molecule, 779.57 g of hydroxy terminated silicone oil (9 parts by mole, having a viscosity of 60 cP to 80 cP at 25° C., hydroxy terminated polydimethylsiloxane commercially available from Gelest, Inc.), and formic acid serving as catalyst were mixed and heated to 110° C., and then stirred for 24 hours to perform a sol-gel reaction, thereby obtaining a star polymer. The volume of the formic acid and the total weight of the core molecule and the hydroxy terminated silicone oil had a ratio of 0.5% (v/w). Subsequently, the formic acid catalyst and the side product methanol were removed by a rotary evaporator (10 torr, 140° C.). The reaction can refer to the corresponding chemical formula in Example 1.

Subsequently, 9.95 g of hexamethyldisilazane (9 parts by mole) serving as a terminating agent was mixed with the star polymer, and then heated to 60° C. to react for 6 hours, thereby obtaining a polymer. The precipitate was filtered out, and the side product ammonia and the excess hexamethyldisilazane in the filtrate were removed by the rotary evaporator (10 torr,)140° C. The reaction can refer to the corresponding chemical formula in Example 1. The polymer had a viscosity of 87 cP at 25° C., a decomposition temperature (Td, 5% weight loss temperature) of 310° C., and a flash point of higher than 300° C.

### Comparative Example 1

12.7 g of tris[3-(trimethoxysilyl)propyl] isocyanurate (1 part by mole) serving as a core molecule, 779.57 g of hydroxy terminated silicone oil (9 parts by mole, having a viscosity of 60 cP to 80 cP at 25° C., hydroxy terminated polydimethylsiloxane commercially available from Gelest, Inc.), and formic acid serving as catalyst were mixed and heated to 110° C., and then stirred for 24 hours to perform a sol-gel reaction, thereby obtaining a star polymer. The volume of the formic acid and the total weight of the core molecule and the hydroxy terminated silicone oil had a ratio of 0.5% (v/w). Subsequently, the formic acid catalyst and the side product methanol were removed by a rotary evaporator (10 torr,)140° C. The reaction can refer to the corresponding chemical formula in Example 1.

Subsequently, 4.98 g of hexamethyldisilazane (4.5 parts by mole) serving as a terminating agent was mixed with the star polymer, and then heated to 60° C. to react for 6 hours, thereby obtaining a polymer. The precipitate was filtered out, and the side product ammonia and the excess hexamethyldisilazane in the filtrate were removed by the rotary evaporator (10 torr,)140° C. The reaction can refer to the corresponding chemical formula in Example 1. The polymer had a viscosity of 97 cP at 25° C., a decomposition temperature (Td, 5% weight loss temperature) of 249° C., and a flash point of 250° C. Accordingly, insufficient amount of the terminating agent would result in the terminal hydroxy group remained in the polymer, which could crosslink to increase the viscosity.

### Comparative Example 2

12.7 g of tris[3-(trimethoxysilyl)propyl] isocyanurate (1 part by mole) serving as a core molecule, 102.08 g of hydroxy terminated silicone oil (9 parts by mole, having a viscosity of 16 cP to 32 cP at 25° C., hydroxy terminated polydimethylsiloxane commercially available from Gelest, Inc.), and formic acid serving as catalyst were mixed and heated to 110° C., and then stirred for 24 hours to perform a sol-gel reaction, thereby obtaining a star polymer. The volume of the formic acid and the total weight of the core molecule and the hydroxy terminated silicone oil had a ratio of 0.5% (v/w). Subsequently, the formic acid catalyst and the side product methanol were removed by a rotary evaporator (10 torr, 140° C.). The reaction can refer to the corresponding chemical formula in Example 1.

Subsequently, 9.95 g of hexamethyldisilazane (9 parts by mole) serving as a terminating agent was mixed with the star polymer, and then heated to 60° C. to react for 6 hours. However, the reaction was gelled during the reaction, and the properties of the gelled result could not be measured. . Accordingly, if the viscosity of the hydroxy terminated silicone oil was too low, the reactivity of the terminal hydroxy group in the star polymer would be too high and crosslink during the terminating reaction.

### Comparative Example 3

12.7 g of tris[3-(trimethoxysilyl)propyl] isocyanurate (1 part by mole) serving as a core molecule, 204.17 g of hydroxy terminated silicone oil (9 parts by mole, having a viscosity of 35 cP to 45 cP at 25° C., hydroxy terminated polydimethylsiloxane commercially available from Gelest, Inc.), and formic acid serving as catalyst were mixed and heated to 110° C., and then stirred for 24 hours to perform a sol-gel reaction, thereby obtaining a star polymer. The volume of the formic acid and the total weight of the core molecule and the hydroxy terminated silicone oil had a ratio of 0.5% (v/w). Subsequently, the formic acid catalyst and the side product methanol were removed by a rotary evaporator (10 torr,)140° C. The reaction can refer to the corresponding chemical formula in Example 1.

Subsequently, 9.95 g of hexamethyldisilazane (9 parts by mole) serving as a terminating agent was mixed with the star polymer, and then heated to 60° C. to react for 6 hours. However, the reaction was gelled during the reaction, and the properties of the gelled result could not be measured. Accordingly, if the viscosity of the hydroxy terminated silicone oil was too low, the reactivity of the terminal hydroxy group in the star polymer would be too high and crosslink during the terminating reaction.

### Comparative Example 4

12.7 g of tris[3-(trimethoxysilyl)propyl] isocyanurate (1 part by mole) serving as a core molecule, 779.17 g of hydroxy terminated silicone oil (9 parts by mole, having a viscosity of 90 cP to 120 cP at 25° C., hydroxy terminated polydimethylsiloxane commercially available from Gelest, Inc.), and formic acid serving as catalyst were mixed and heated to 110° C., and then stirred for 24 hours to perform a sol-gel reaction, thereby obtaining a star polymer. The volume of the formic acid and the total weight of the core molecule and the hydroxy terminated silicone oil had a ratio of 0.5% (v/w). Subsequently, the formic acid catalyst and the side product methanol were removed by a rotary evaporator (10 torr,)140° C. The reaction can refer to the corresponding chemical formula in Example 1.

The star polymer that was not terminated by a terminating agent had a viscosity of 131 cP at 25° C., a decomposition temperature (Td, 5% weight loss temperature) of 250° C., and a flash point of 248° C. Accordingly, the terminal hydroxy groups of the star polymer that was not terminated by a terminating agent would crosslink to increase the viscosity.

Example 4

11.25 g of 1,2-bis(triethoxysilyl)ethane (1 part by mole) serving as a core molecule, 800 g of hydroxy terminated silicone oil (6 parts by mole, having a viscosity of 60 cP to 80 cP at 25° C., hydroxy terminated polydimethylsiloxane commercially available from Kelly Chemical Co.), and formic acid serving as catalyst were mixed and heated to 110° C., and then stirred for 24 hours to perform a sol-gel reaction, thereby obtaining a star polymer. The volume of the formic acid and the total weight of the core molecule and the hydroxy terminated silicone oil had a ratio of 1% (v/w). Subsequently, the formic acid catalyst and the side product methanol were removed by a rotary evaporator (10 torr,) 140° C. The reaction is shown below:

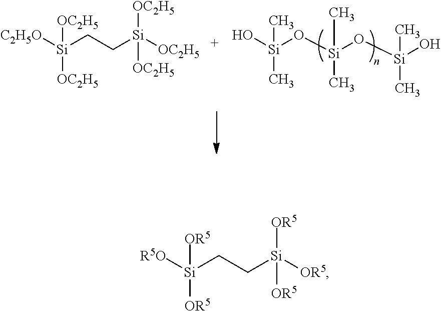

wherein R⁵ is

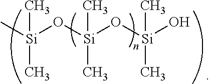

Subsequently, 6.64 g of hexamethyldisilazane (6 parts by mole) serving as a terminating agent was mixed with the star polymer, and then heated to 60° C.to react for 6 hours, thereby obtaining a polymer. The precipitate was filtered out, and the side product ammonia and the excess hexamethyldisilazane in the filtrate were removed by the rotary evaporator (10 torr,)140° C. The reaction is shown below:

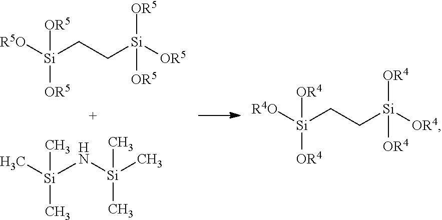

wherein R⁴ is

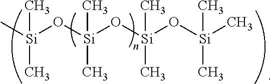

The polymer had a viscosity of 86 cP at 25° C., a decomposition temperature (Td, 5% weight loss temperature) of 335° C., and a flash point of higher than 300° C.

### Comparative Example 5

11.25 g of 1,2-bis(triethoxysilyl)ethane (1 part by mole) serving as a core molecule, 533 g of hydroxy terminated silicone oil (4 parts by mole, having a viscosity of 90 cP to 120 cP at 25° C., hydroxy terminated polydimethylsiloxane commercially available from Gelest, Inc.), and formic acid serving as catalyst were mixed and heated to 110° C., and then stirred for 24 hours to perform a sol-gel reaction, thereby obtaining a star polymer. The volume of the formic acid and the total weight of the core molecule and the hydroxy terminated silicone oil had a ratio of 1% (v/w). Subsequently, the formic acid catalyst and the side product methanol were removed by a rotary evaporator (10 torr,)140° C. The reaction can refer to the corresponding chemical formula in Example 4.

Subsequently, 6.64 g of hexamethyldisilazane (6 parts by mole) serving as a terminating agent was mixed with the star polymer, and then heated to 60° C. to react for 6 hours, thereby obtaining a polymer. The precipitate was filtered out, and the side product ammonia and the excess hexamethyldisilazane in the filtrate were removed by the rotary evaporator (10 torr,)140° C. The reaction can refer to the corresponding chemical formula in Example 4. The polymer had a viscosity of 78 cP at 25° C., a decomposition temperature (Td, 5% weight loss temperature) of 225° C., and a flash point of 232° C. Accordingly, if the amount of the hydroxy terminated silicone oil was insufficient, the flash point of the polymer could not be efficiently enhanced.

### Comparative Example 6

Commercially available silicone oil (DMS-S21 commercially available from Gelest, Inc.) was selected to measure its properties. DMS-S21 had a viscosity of 80 cP at 25° C., a decomposition temperature (Td, 5% weight loss temperature) of 194° C., and a flash point of 205° C. Obviously, the thermal stability of DMS-S21 was insufficient.

It will be apparent to those skilled in the art that various modifications and variations can be made to the disclosed methods and materials. It is intended that the specification and examples be considered as exemplary only, with the true scope of the disclosure being indicated by the following claims and their equivalents. What is claimed is:

1. A polymer, being formed by:
reacting a terminating agent with a star polymer, the star polymer is formed by reacting a core molecule with a hydroxy terminated silicone oil, and the core molecule includes a plurality of alkoxysilyl groups, a plurality of hydroxysilyl groups, or a combination thereof.

2. The polymer as claimed in claim 1, wherein the core molecule has a chemical structure of 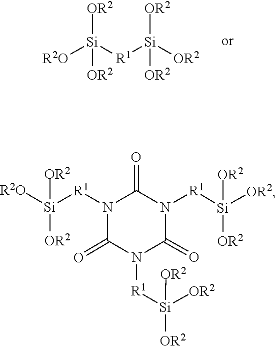
wherein each of R¹ is independently of C₂₋₅ alkylene group, and each of R² is independently of H or C₁₋₃ alkyl group.

3. The polymer as claimed in claim 2, wherein the core molecule comprises 1,2-bis(triethoxysilyl)ethane or tris[3-(trimethoxysilyl)propyl] isocyanurate.

4. The polymer as claimed in claim 1, wherein the hydroxy terminated silicone oil has a chemical structure of 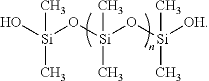
wherein n is a repeating number, and the hydroxy terminated silicone oil has a viscosity of 60 cP to 120 cP at 25° C.

5. The polymer as claimed in claim 1, wherein the alkoxysilyl groups, hydroxysilyl groups, or a combination thereof in the core molecule and the hydroxy groups in the hydroxy terminated silicone oil have a molar ratio of 1:1.5 to 1:2.5.

6. The polymer as claimed in claim 1, wherein the terminating agent has a chemical structure of 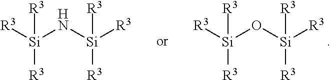
wherein each of R³ is independently of H, methyl group, or ethyl group.

7. The polymer as claimed in claim 1, wherein the alkoxysilyl groups, hydroxysilyl groups, or a combination thereof in the core molecule and the terminating agent have a molar ratio of 1:1 to 1:1.2.

8. The polymer as claimed in claim 1, having a chemical structure of 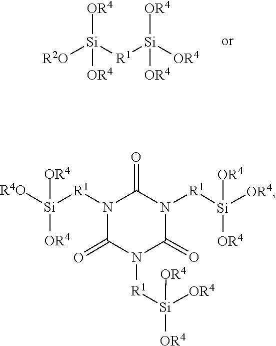
wherein each of R¹ is independently C₂₋₅ alkylene group, each of R⁴ is 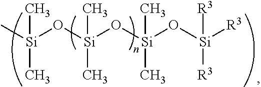
wherein n is a repeating number, and each of R³ is independently of H, methyl group, or ethyl group.

9. The polymer as claimed in claim 1, wherein the core molecule is reacted with the hydroxy terminated silicone oil in the presence of a catalyst, and the catalyst comprises formic acid, acetic acid, hydrochloric acid, or a combination thereof.

10. The polymer a claimed in claim 9, wherein the total weight of the core molecule and the hydroxy terminated silicone oil and the volume of the catalyst have 2 a ratio of 100:0.01 to 100:2.

11. A dielectric fluid, comprising:
100 parts by weight of the polymer as claimed in claims 1;
0.01 to 5 parts by weight of antioxidant; and
0.0001 to 0.01 parts by weight of metal deactivator.

12. The dielectric fluid as claimed in claim 11, wherein the antioxidant comprises di-tert-butyl-p-cresol, 2,6-di-tert-butyl-4-methylphenol, 2,5-di-tert-butyl-hydroquinone, 2,6-di-tert-butyl-4-ethylphenol, 4,4-methylenebis-2,6-di-tert-butylphenol, N,N-di-second-butyl-p-phenylenediamine, alkylated diphenylamine, di-isooctyl di-aniline, octadecyl 3-(3,5-di-tert-butyl-4-hydroxyphenyl) propionate, or a combination thereof.

13. The dielectric fluid as claimed in claim 11, wherein the metal deactivator comprises triazole compound or diazole compound.

14. The polymer as claimed in claim 1, wherein the dielectric fluid and the hydroxy terminated silicone oil have a difference in viscosity of 0.1 cP to 10 cP at 2 25° C.

15. A cooling system, comprising:
a container;
the dielectric fluid as claimed in claim 11 disposed in the container;
an electronic element partially or entirely immersed in the dielectric fluid, wherein heat generated by the electronic element is transferred to the dielectric fluid; and
a heat exchanger disposed in the dielectric fluid for cooling the dielectric fluid.
